(19) United States
(12) Patent Application Publication
(10) Pub. No.: US 2025/0194387 A1
(43) Pub. Date: Jun. 12, 2025

(54) DISPLAY DEVICE

(71) Applicant: LG Display Co., Ltd., Seoul (KR)

(72) Inventors: TaeHyung LEE, Paju-si (KR); SangChul JUNG, Paju-si (KR); KyungRok KIM, Paju-si (KR)

(73) Assignee: LG Display Co., Ltd., Seoul (KR)

(21) Appl. No.: 18/901,778

(22) Filed: Sep. 30, 2024

(30) Foreign Application Priority Data
Dec. 12, 2023 (KR) 10-2023-0180015

(51) Int. Cl. H10K 59/80; H10K 59/122

(52) U.S. Cl. CPC H10K 59/8792; H10K 59/122

(57) ABSTRACT

Embodiments of the present disclosure relates to a display device including a substrate, a blocking layer disposed on the substrate, and a low-reflection film disposed below the blocking layer and including at least one metal element and oxygen, the content of oxygen being in a range of 31.6 at % to 47.3 at %. According to embodiments of the present disclosure, it is possible to reduce the reflectance caused by external light.

### CROSS REFERENCE TO RELATED APPLICATION

This application claims priority from Korean Patent Application No. 10-2023-0180015, filed on Dec. 12, 2023, which is hereby incorporated by reference for all purposes as if fully set forth herein.

### BACKGROUND

### Technical Field

The present disclosure relates to a display device.

### Discussion of the Related Art

As the information society develops, there is increasing a demand for a display device for displaying images in various forms. Among display devices, a light emitting display device of a self-luminous type may have an advantage of being lightweight and thin due to no need for a separate backlight.

In this case, a light emitting display device may require a separate configuration to prevent the reflection of the external light. Therefore, there may increase the manufacturing cost of the light emitting display device due to the addition of the separate configuration. In addition, since it is required an additional process for attaching the separate configuration to the light emitting display device, the manufacturing process of the light emitting display device may become complicated. Furthermore, since the thickness of the light emitting display device may be increased by additional configurations, there may be a problem of not satisfying the user's need to reduce the thickness of the light emitting display device.

In addition, the more external light is reflected by the display device, the more images of objects outside the display device are reflected on the display device. Therefore, there may be a problem in which the user feels uncomfortable due to poor reflection color.

### SUMMARY

Accordingly, embodiments of the present disclosure are directed to a display device that substantially obviates one or more of the problems due to limitations and disadvantages of the related art.

An aspect of the present disclosure is to provide a display device capable of reducing reflectance from external light.

Another aspect of the present disclosure is to provide a display device capable of improving reflection color.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate, a blocking layer disposed on the substrate, and a low-reflection film disposed below the blocking layer and including at least one metal element and oxygen, a content of oxygen being in a range of 31.6 at % to 47.3 at %.

In another aspect, a display device comprises a substrate, and at least one material layer including a first material layer forming an electrode or a line on the substrate and including a metal element, and a second material layer disposed below the first material layer and including oxygen, a content of oxygen included in the second material layer being in a range of 31.6 at % to 47.3 at %.

In another aspect, a display device comprises a substrate, a blocking layer disposed on the substrate, a transistor disposed on the blocking layer and including a source electrode, a drain electrode, and a gate electrode, and a low-reflection film disposed below the blocking layer and at least one of the source electrode, the drain electrode, and the gate electrode, and including at least one metal element and oxygen, a content of the oxygen being in a range of 31.6 at % to 47.3 at %.

According to embodiments of the present disclosure, there may provide a display device capable of reducing the reflectance from external light.

According to embodiments of the present disclosure, there may provide a display device capable of improving the reflection color.

According to embodiments of the present disclosure, there may provide a display device capable of reducing the reflectance from external light, thereby enabling low power consumption through the efficient operation of a device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 illustrates an example of the structure of a display device and a circuit structure included in a subpixel according to embodiments of the present disclosure.

FIG. 2 illustrates an example of a cross-sectional structure of a conventional display device.

FIG. 3 is an enlarged view of part A of FIG. 2.

FIG. 4 illustrates an example of a cross-sectional structure of a display device according to embodiments of the present disclosure.

FIG. 5 is an enlarged view of part B of FIG. 4.

FIG. 6 is a diagram illustrating an upper limit of a composition range of a portion of configurations included in a display device according to embodiments of the present disclosure.

FIG. 7 is a diagram illustrating a lower limit of the composition range of a portion of configurations included in a display device according to embodiments of the present disclosure.

FIGS. 8A and 8B illustrate changes in optical characteristics of a display device according to modifications in configurations included in a display device according to embodiments of the present disclosure.

FIGS. 9 to 11 illustrate another example of a cross-sectional structure of a display device according to embodiments of the present disclosure.

FIG. 12 is an enlarged view of part C of FIG. 11.

FIG. 13 illustrates optical characteristics according to wavelength of a display device shown in FIG. 11.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, embodiments will be described in detail with reference to the accompanying drawings.

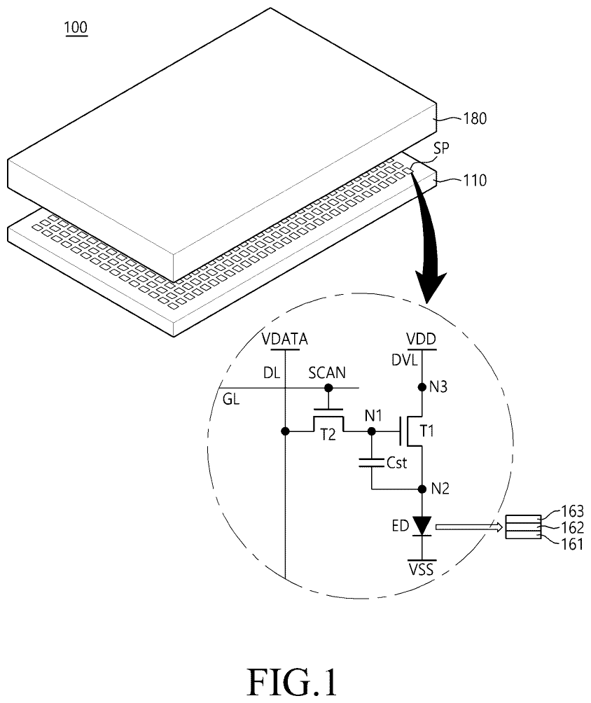

FIG. 1 illustrates an example of the structure of a display device and a circuit structure included in a subpixel according to embodiments of the present disclosure.

Referring to FIG. 1, a plurality of subpixels SP may be disposed in a display area of a display device 100.

Each of the plurality of subpixels SP may include a light emitting device ED and a subpixel circuit unit configured to drive the light emitting device ED.

The subpixel circuit unit may include a driving transistor T1 for driving the light emitting device ED, a scan transistor T2 for transferring the data voltage VDATA to a first node N1 of the driving transistor T1, and a storage capacitor Cst for maintaining a constant voltage during one frame.

The driving transistor T1 may include a first node N1 to which a data voltage is applied, a second node N2 electrically connected to the light emitting device ED, and a third node N3 to which the driving voltage VDD is applied from a driving voltage line DVL. In the driving transistor T1, the first node N1 may be a gate node, the second node N2 may be a source node or a drain node, and the third node N3 may be a drain node or a source node. Hereinafter, for convenience of explanation, there illustrates a case in which the first node N1 is a gate node, the second node N2 is a source node, and the third node N3 is a drain node in the driving transistor T1, as an example.

The light emitting device ED may include an anode electrode 161, an intermediate layer 162, and a cathode electrode 163. The anode electrode 161 may be a pixel electrode disposed in each subpixel SP, and may be electrically connected to the second node N2 of the driving transistor T1 of each subpixel SP. The cathode electrode 163 may be a common electrode commonly disposed in the plurality of subpixels SP, and a base voltage VSS may be applied thereto.

Alternatively, the anode electrode 161 may be a common electrode, and the cathode electrode 163 may be a pixel electrode. Hereinafter, for convenience of explanation, it is assumed that anode electrode 161 is a pixel electrode and the cathode electrode 163 is a common electrode.

The light emitting device ED may be an organic light emitting diode (OLED), an inorganic light emitting diode, or a quantum dot light emitting device. In the case that the light emitting device ED is an organic light emitting diode, the intermediate layer 162 in the light emitting device ED may include an organic light emitting layer containing an organic material.

The scan transistor T2 may be controlled on-off by a scan signal SCAN, which is a gate signal applied through a gate line GL, and the scan transistor T2 may be electrically connected between the first node N1 of the driving transistor T1 and the data line DL.

The storage capacitor Cst may be electrically connected between the first node N1 and the second node N2 of the driving transistor T1.

The subpixel circuit unit may have a 2T1C structure including two transistors T1 and T2 and one capacitor Cst, and in some cases, may further include one or more transistors, or may further include one or more capacitors.

The storage capacitor Cst may be an external capacitor intentionally designed outside the driving transistor T1 rather than a parasitic capacitor (e.g., Cgs, Cgd) which is an internal capacitor existing between the first node N1 and the second node N2 of the driving transistor T1. Each of the driving transistor T1 and the scan transistor T2 may be an n-type transistor or a p-type transistor.

Circuit elements within each subpixel, in particular, light emitting devices EDs implemented with organic light-emitting diodes OLEDs containing organic materials may be vulnerable to external moisture or oxygen. Accordingly, an encapsulation layer 180 may be disposed on the display panel 110 to prevent oxygen from penetrating into the circuit elements (particularly, the light emitting devices ED). The encapsulation layer 180 may be disposed to cover the light emitting device ED.

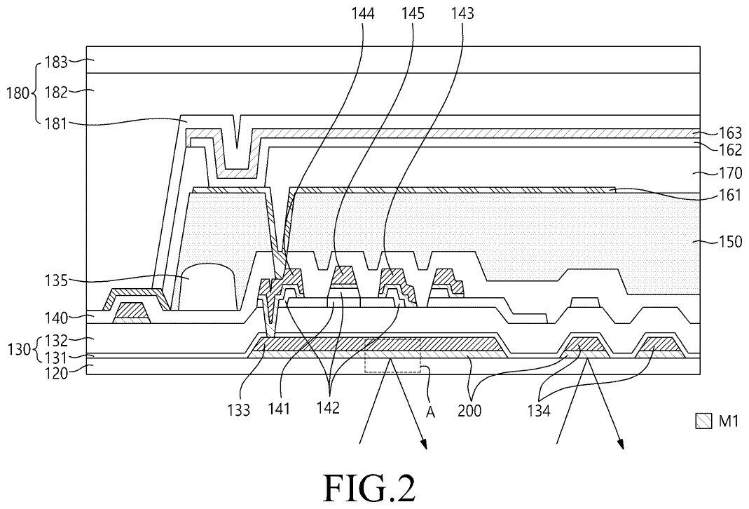

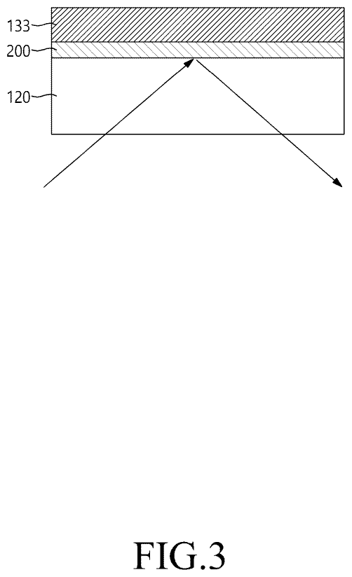

FIG. 2 illustrates an example of a cross-sectional structure of a conventional display device. FIG. 3 is an enlarged view of part A of FIG. 2.

Referring to FIG. 2, a display device 100 may include a substrate 120.

The substrate 120 may serve to support various components of the display device 100. The substrate 120 may be made of glass or plastic material.

In the case that the display device 100 is a bottom emission type, the substrate 120 may be made of a transparent material such as glass in order to emit emitted light to the outside of the display device 100.

A buffer layer 130, a blocking layer 133, and a wiring electrode 134 for a line may be disposed on the substrate 120.

The buffer layer 130 may be disposed on the entire surface of the substrate 120.

The buffer layer 130 may improve the adhesion between the layers formed on the buffer layer and the substrate 120, and may play the role of blocking various types of defects such as alkaline components leaking from the substrate 120.

The buffer layer 130 may include a first buffer layer 131 and a second buffer layer 132 disposed on the first buffer layer 131. The first buffer layer 131 and the second buffer layer 132 may be made of silicon nitride (SiNx) or silicon oxide (SiOx).

The blocking layer 133 and the wiring electrodes 134 may be disposed between the substrate 120 and the first buffer layer 131. That is, the first buffer layer 131 may be disposed to cover the blocking layer 133 and the wiring electrodes 134.

The blocking layer 133 may be disposed below the driving transistor T1. The blocking layer 133 may have an area larger than that of a semiconductor pattern 141, which will be described later.

The blocking layer 133 may prevent malfunction of the semiconductor pattern 141 which may occur when external incident light from the display device 100 is irradiated to the semiconductor pattern 141.

The blocking layer 133 may be disposed using an opaque conductive material to block light incident from the outside of the display device 100. Alternatively, a metal with low reflectivity may be further disposed under the blocking layer 133 to block light incident from the outside. For example, as shown in FIG. 2, a low-reflection metal layer 200 may be disposed under the blocking layer 133 to block light incident from the outside. The low-reflection metal layer 200 may be formed of a single layer or multiple layers of any one of molybdenum (Mo), titanium (Ti), aluminum (Al), chromium (Cr), nickel (Ni), neodymium (Nd), and tungsten (W) or an alloy thereof, but is not limited thereto.

If the low-reflection metal layer 200 is disposed, a part of the light incident on the display device 100 may be reflected by the low-reflection metal layer 200 and directed back to the outside.

The wiring electrodes 134 may include a capacitor electrode and may include electrodes for various wiring, such as a wiring connected to a data line. The wiring electrodes 134 may be formed of the same material as the blocking layer 133. In addition, the low-reflection metal layer 200 may be disposed below the wiring electrodes 134. Accordingly, as shown in FIG. 2, some of the light incident on the display device 100 may be reflected by the wiring electrodes 134 and directed back to the outside.

In addition to the blocking layer 133 and the wiring electrodes 134, the low-reflection metal layer 200 may be additionally disposed below a source electrode 143, a drain electrode 144, and a gate electrode 145 of the driving transistor T1, which will be described later. In addition, the low-reflection metal layer 200 may be additionally disposed under metals with high reflectivity disposed inside the display device 100. All of the low-reflection metal layers 200 may be made of the same material layer M1.

A color filter 135, a driving transistor T1, and an insulating layer 140 may be disposed on the buffer layer 130.

In the case that the display device 100 is a bottom-emission type, the color filter 135 may be located below the light emitting device ED, as shown in FIG. 2. In addition, the color filter 135 may be disposed to overlap an emission area of the light emitting device ED.

A semiconductor pattern 141 of the driving transistor T1 may be disposed on the buffer layer 130. The semiconductor pattern 141 may include a channel area in which a channel through which electrons or holes move is formed. A source area and a drain area, which are conducted areas through a doping process, may exist on both sides of the channel area.

An interlayer insulating layer 142 may be disposed in some areas on the semiconductor pattern 141. A source electrode 143 and a drain electrode 144 may be disposed on the interlayer insulating layer 142. The source electrode 143 and the drain electrode 144 may be electrically connected to the conductive source and drain areas of the semiconductor pattern 141, respectively. Additionally, the drain electrode 144 may be electrically connected to the blocking layer 133 through a contact hole.

The source electrode 143 and the drain electrode 144 may be formed as a single layer or multiple layers made of any one of molybdenum (Mo), copper (Cu), titanium (Ti), aluminum (Al), chromium (Cr), gold (Au), nickel (Ni), and neodymium (Nd) or an alloy thereof, but is not limited thereto.

The gate electrode 145 may be disposed in some areas on the interlayer insulating layer 142. The interlayer insulating layer 142 below the gate electrode 145 may also be referred to as a gate insulating layer. The gate electrode 145 may be formed as a single layer or multiple layers made of any one of molybdenum (Mo), copper (Cu), titanium (Ti), aluminum (Al), chromium (Cr), gold (Au), nickel (Ni), and neodymium, or an alloy thereof, but is not limited thereto

An insulating layer 140 may be disposed to cover the gate electrode 145, the source electrode 143, and the drain electrode 144.

The insulating layer 140 and the interlayer insulating layer 142 may be formed of an insulating inorganic material such as silicon nitride (SiNx) or silicon oxide (SiOx).

A planarization layer 150 may be disposed on the insulating layer 140. The planarization layer 150 may be disposed to cover the driving transistor T1. The planarization layer 150 may protect the transistor disposed below, and may alleviate or flatten the steps caused by various patterns.

An anode electrode 161 may be disposed on the planarization layer 150.

If the display device 100 is a bottom emission type, the anode electrode 161 may be disposed using a transparent conductive material capable of transmitting light. For example, the anode electrode 161 may be formed of at least one of indium tin oxide (ITO) and indium zinc oxide (IZO), but is not limited thereto.

An intermediate layer 162 and a bank layer 170 may be disposed on the anode electrode 161.

The intermediate layer 162 may include one of a red organic emission layer, a green organic emission layer, a blue organic emission layer, and a white organic emission layer in order to emit light of a specific color.

In addition, the intermediate layer 162 may further include a hole injection layer, a hole transport layer, an electron injection layer, and an electron transport layer in addition to the organic emission layer, but is not limited thereto.

The bank layer 170 may have a bank hole which exposes the anode electrode 161 corresponding to the light emission area.

The bank layer 170 may be made of at least one of an inorganic insulating material such as silicon nitride (SiNx) or silicon oxide (SiOx), or an organic insulating materials such as BCB (BenzoCycloButene), acryl resin, epoxy resin, phenolic resin, polyamide resin, or polyimide resin, but is not limited thereto. In addition, the bank layer 170 may be made of a transparent material.

A cathode electrode 163 may be disposed on the intermediate layer 162.

In the case that the display device 100 is a bottom emission type, the cathode electrode 163 may be a reflective electrode that reflects light, and may be disposed using an opaque conductive material. For example, the cathode electrode 163 may be formed of at least one of silver (Ag), aluminum (Al), gold (Au), molybdenum (Mo), tungsten (W), chromium (Cr), or alloys thereof.

An encapsulation layer 180 may be disposed on the cathode electrode 163.

The encapsulation layer 180 may protect the light emitting device ED from external moisture, oxygen, or foreign substances.

The encapsulation layer 180 may include a first encapsulation layer 181, a second encapsulation layer 182 disposed on the first encapsulation layer 181, and a third encapsulation layer 183 disposed on the second encapsulation layer 182.

The first encapsulation layer 181 may be made of an inorganic material such as silicon nitride (SiNx), but is not limited thereto. The second encapsulation layer 182 may be made of calcium oxide (CaO) capable of absorbing moisture, but is not limited thereto. The third encapsulation layer 183 may be made of metal, but is not limited thereto.

As described above with reference to FIG. 2, a conventional display device 100 may include components made of an opaque conductive material, that is, the blocking layer 133, the wiring electrodes 134, and a source electrode 143, a drain electrode 144, a gate electrode 145 of the driving transistor T1, etc.

Since the display device 100 includes components made of an opaque conductive material, the reflectance of external light may increase, which may cause problems of interfering with the user's field of view. To solve this problem, a low-reflection metal layer 200 may be disposed below the components made of an opaque conductive material as described above.

Hereinafter, it will be described an example in which the low-reflection metal layer 200 is disposed below the blocking layer 133 in detail with reference to FIG. 3.

Referring to FIG. 3, the blocking layer 133 may be, for example, copper (Cu). The low-reflection metal layer 200 may be disposed below the blocking layer 133. The low-reflection metal layer 200 may be MoTi, for example.

The low-reflection metal layer 200 may have a thickness of 100 Å. When the thickness of the low-reflection metal layer 200 is 100 Å, the proportion of light reflected from the surface of the low-reflection metal layer 200 and directed back to the outside, that is, the blocking layer reflectance is 36%.

In addition, a unit film reflectance of the product unit of the entire display devices 100 including the low-reflection metal layer 200 is 36.5%.

That is, even when the low-reflection metal layer 200 is disposed below the blocking layer 133, the unit film reflectance of the product unit is 36% or more, as in the above-described example, and thus may interfere with the user's field of view. In order to maintain reflective visibility without interfering with the user's field of vision, it is important to reduce the unit film reflectance of the product unit to 36% or less. The unit film reflectance of a product unit may also be expressed as a reflectance by external light.

In addition, since the unit film reflectance of the product unit is high, the image of objects outside the display device may be reflected in the display device, resulting in poor reflection color.

Hereinafter, it will be described a method for solving the above problems with reference to embodiments of the present disclosure.

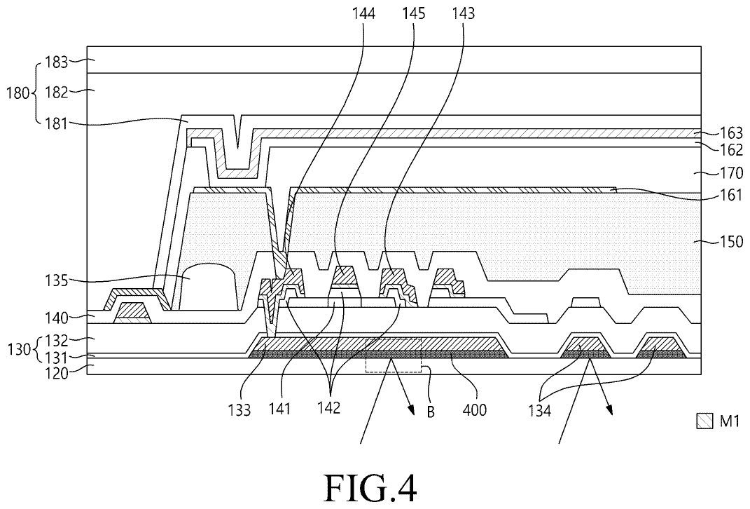

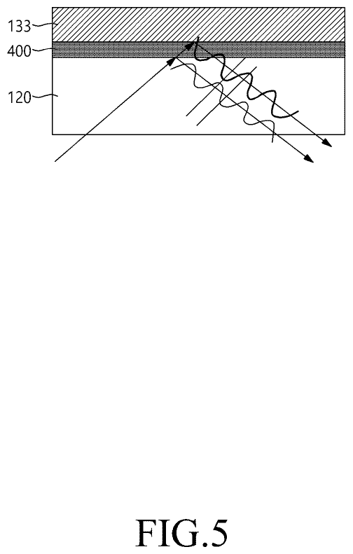

FIG. 4 illustrates an example of a cross-sectional structure of a display device according to embodiments of the present disclosure. FIG. 5 is an enlarged view of part B of FIG. 4.

Compared to the display device in FIG. 2, FIG. 4 is substantially the same except for the arrangement of a low-reflection film 400 instead of the low-reflection metal layer 200, and thus redundant description will be omitted.

The display device 100 according to an embodiment of the present disclosure may further include a low-reflection film 400.

Referring to FIG. 4, the low-reflection film 400 may be disposed below the blocking layer 133 and the wiring electrodes 134. The low-reflection film 400 may be disposed to cover both the lower surfaces of the blocking layer 133 and the wiring electrodes 134. That is, the area of the lower surface of the low-reflection film 400 may be equal to or larger than the area of the lower surface of the blocking layer 133 or the wiring electrodes 134.

The low-reflection film 400 may be disposed between the blocking layer 133 and the substrate 120. Specifically, an upper surface of the low-reflection film 400 may contact a lower surface of the blocking layer 133, and a lower surface of the low-reflection film 400 may contact an upper surface of the substrate 120.

The low-reflection film 400 may be disposed between the wiring electrodes 134 and the substrate 120. Specifically, an upper surface of the low-reflection film 400 may be in contact with a lower surface of the wiring electrodes 134, and a lower surface of the low-reflection film 400 may be in contact with an upper surface of the substrate 120.

The low-reflection film 400 may be made of a material which transmits a portion of incident light.

Specifically, the low-reflection film 400 may contain metal elements and oxygen.

The metal elements may include at least one of molybdenum (Mo), titanium (Ti), aluminum (Al), chromium (Cr), nickel (Ni), neodymium (Nd), tungsten (W), tantalum, yttrium (Y), zinc (Zn), barium (Ba), gallium (Ga), indium (In), magnesium (Mg), and tin (Sn).

In addition, the low-reflection film 400 may include carbon atoms. The carbon atoms may be impurities generated during the manufacturing process of the low-reflection film 400, and may be partially included in the low-reflection film 400 when the low-reflection film 400 is exposed to air or comes into contact with organic substances.

The low-reflection film 400 may be formed through a sputtering process. Sputtering target materials may include metals and oxides.

The sputtering target material used to form the low-reflection film 400 may include at least one metal selected from molybdenum (Mo), titanium (Ti), nickel (Ni), and tungsten (W), and may include at least one oxide of titanium dioxide (TiO₂), tantalum pentoxide (Ta₂O₅), molybdenum oxide (MoOx), niobium oxide (Nb₂O₅), yttrium oxide (Y₂O₃), silicon oxide (SiO₂), zinc oxide (ZnO), barium oxide (BaO), gallium zinc oxide (GZO), indium oxide (In₂O₃), magnesium oxide (MgO), tungsten trioxide (WO₃), tin oxide (SnO₂), and zinc tin oxide (ZTO).

As an example, the low-reflection film 400 may be formed from a sputtering target of molybdenum (Mo) and titanium dioxide (TiO₂). In this case, the low-reflection film 400 may have a composition ratio of 41.6 at % molybdenum (Mo), 17.9 at % titanium (Ti), 35.4 at % oxygen, and 5.1 at % carbon. However, it is not limited thereto.

As the low-reflection film 400 is formed from a sputtering target material of metal and oxide, that is, as the low-reflection film 400 contains oxygen atoms, some of the light incident on the low-reflection film 400 may be transmitted.

Specifically, referring to FIG. 5, light incident from the outside of the display device 100 through the substrate 120 may be partially reflected on the surface of the low-reflection film 400, and some of the light may transmit through the low-reflection film 400.

That is, since the low-reflection film 400 contains some metal elements, which are opaque conductive materials, the low-reflection film 400 may reflect a part of the incident light as shown in FIG. 5. In addition, since the low-reflection film 400 contains some oxygen, a part of the incident light may pass through the low-reflection film 400. In this case, the amount of light passing through the low-reflection film 400 may vary depending on a content of the oxygen contained in the low-reflection film 400. That is, the transmittance of the low-reflection film 400 may vary depending on the content of oxygen contained in the low-reflection film 400.

The light passing through the low-reflection film 400 may be reflected by the blocking layer 133. Since the blocking layer 133 is made of an opaque conductive material as described above, most of the light incident on the blocking layer 133 may be reflected.

The light reflected from the blocking layer 133 may pass through the low-reflection film 400 and the substrate 120, and may proceed to the outside of the display device 100.

In this case, as shown in FIG. 5, the light reflected from the blocking layer 133 and passing through the low-reflection film 400 may cause destructive interference with the light reflected from the low-reflection film 400.

In the case that the light reflected from the blocking layer 133 and passing through the low-reflection film 400 causes destructive interference with the light reflected from the low-reflection film 400, the amount of light reflected from the blocking layer 133 may decrease. That is, when the low-reflection film 400 is disposed, a part of the light reflected from the surface of the blocking layer 133 may disappear due to destructive interference, so that the blocking layer reflectance may be reduced compared to the case where the low-reflection film 400 is not disposed or the low-reflection metal layer 200 is disposed.

In addition, by reducing the blocking layer reflectance, there may be improved the problem of poor reflection color due to the image of an object existing outside the display device 100 being partially reflected in the display device 100.

As described above, in order to reduce the blocking layer reflectance, there is required to maximize the amount of light destructively interfered by the low-reflection film 400.

Here, the degree of destructive interference of light may vary depending on a refractive index of the low-reflection film 400. Since the refractive index of the low-reflection film 400 may vary depending on the content of oxygen contained in the low-reflection film 400, it is necessary to appropriately adjust the content of oxygen contained in the low-reflection film 400.

If the content of oxygen contained in the low-reflection film 400 is too high, there may cause wiring defects in the blocking layer 133, etc.

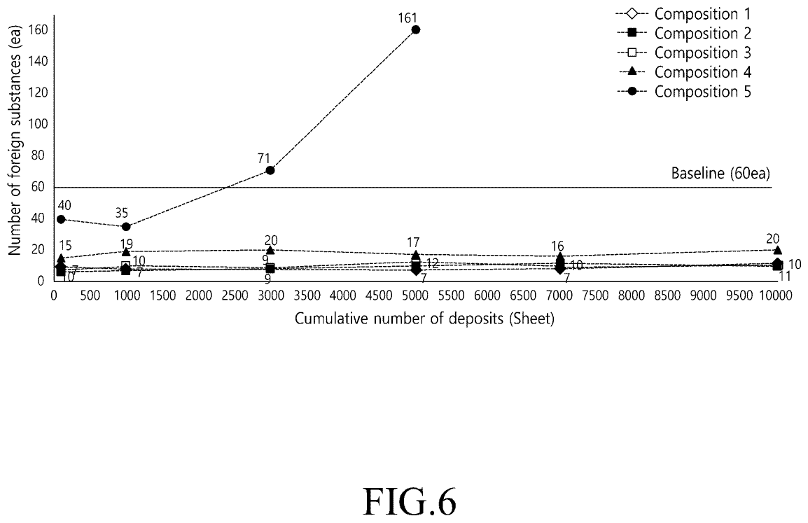

FIG. 6 is a diagram illustrating an upper limit of a composition range of a portion of configurations included in a display device according to embodiments of the present disclosure.

Referring to FIG. 6, there is illustrated the number of foreign substances which may occur depending on the production volume (or number of sputtering depositions) of the low-reflection film 400 when the low-reflection film 400 is manufactured from sputtering targets with different oxide contents.

Here, the foreign substance may refer to materials which are partially removed from an oxide target as the film density of the oxide target decreases and adhesion decreases during the sputtering process of forming the low-reflection film 400. Some foreign substance may fall onto the substrate 120 or the low-reflection film 400 during the sputtering process. If foreign substances fall off, the wiring or electrodes to be deposited later may not be deposited properly, which may result in wiring defects.

In order to prevent wiring defects, it is required to minimize the number of foreign substances, and it is desirable that the number of foreign substances does not exceed 60.

Referring to FIG. 6, in the case that the oxide contained in the sputtering target is titanium oxide (TiO₂), if the oxide content is the same as a composition 1 (20 wt %), a composition 2 (25 wt %), a composition 3 (35 wt %), and a composition 4 (45 wt %), there is confirmed that the number of foreign substances is maintained below 60 even when the production volume of the low-reflection film 400 increases. However, when the oxide content is the same as a composition 5 (55 wt %), the number of foreign substances may be more than 60, and the number of foreign substances may increase as the production volume of the low-reflection film 400 increases.

Therefore, in order to prevent wiring defects due to the generation of foreign substances, the oxide content of the sputtering target may be preferably 45 wt % or less, and the content of oxygen of the low-reflection film 400 may be accordingly preferably 47.3 at % or less.

In addition, if the content of oxygen contained in the low-reflection film 400 is too low, the blocking layer reflectance may increase since the content of the metal element, which is a relatively opaque conductive material, is high.

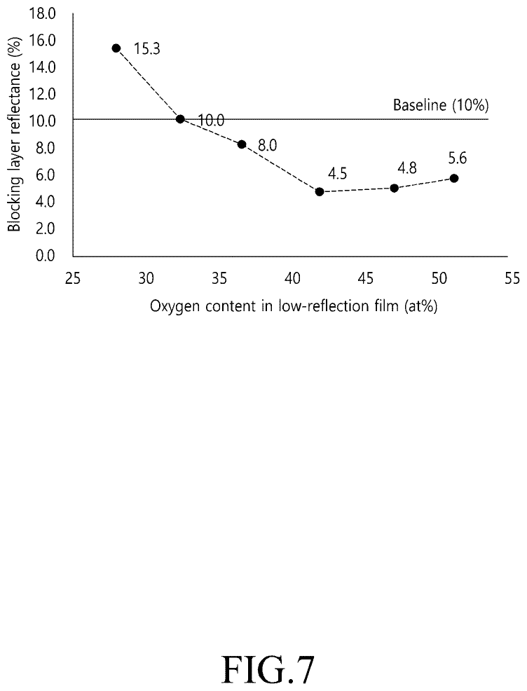

FIG. 7 is a diagram illustrating a lower limit of the composition range of a portion of configurations included in a display device according to embodiments of the present disclosure.

Referring to FIG. 7, there can be seen that when the content of oxygen falls below 31.6 at %, the blocking layer reflectance increases to 10% or more.

Therefore, in order to prevent the increase of the blocking layer reflectance, it is preferable that the content of oxygen of the low-reflection film 400 is 31.6 at % or more.

In summary, the content of oxygen contained in the low-reflection film 400 may be required to at least 31.6 at % or more to prevent the blocking layer reflectance from becoming too high, and may be required to be less than 47.3 at % to prevent wiring defects caused by foreign substances generated during the sputtering process. In addition, since the low-reflection film 400 is formed using the above-mentioned metal and oxide as a sputtering target material, the proportion of the oxide target containing oxygen is required to be set in the range from 25 wt % to 45 wt % of the total target to satisfy the above condition.

The specific composition ratio within the composition range of the low-reflection film 400 may be the same as the composition ratio listed in Table 1 below.

TABLE 1

| | | | | | Blocking |
|---|---|---|---|---|---|
| | | | | | layer |
| | Atomic weight ratio of low-reflection | | | | reflectance |
| | film (400) (at %) | | | | (%, at |
| Compositions | Mo | Ti | O | C | 550 nm) |
| 1 | 47.5 | 15.9 | 31.6 | 5.0 | 10.0 |
| 2 | 41.6 | 17.9 | 35.4 | 5.1 | 8.0 |
| 3 | 31.3 | 21.1 | 42.0 | 5.6 | 4.5 |
| 4 | 23.8 | 23.6 | 47.3 | 5.4 | 4.8 |

Table 1 illustrates examples of composition ratios within the optimal composition ratio range of the low-reflection film 400 described with reference to FIG. 7 and the blocking layer reflectance accordingly.

As described above, the composition of the low-reflection film 400 may vary depending on a weight composition ratio (wt %) of the sputtering target. In addition, the ratio between metal elements included in the low-reflection film 400 may also vary depending on the weight composition ratio (wt %) of the sputtering target. As the weight composition ratio of the metal (molybdenum) contained in the sputtering target increases, the ratio of molybdenum in the low-reflection film 400 increases, and as the weight composition ratio of the oxide (titanium dioxide) contained in the sputtering target increases, the ratio of titanium contained in the low-reflection film 400 increases.

In addition, referring to Table 1 above, when the content of oxygen is 31.6 at %, molybdenum may have a ratio of 47.5 at % and titanium may have a ratio of 15.9 at %. In this case, the ratio of molybdenum, titanium and oxygen is 3:1:2.

When the content of oxygen is 35.4 at %, molybdenum may have a ratio of 41.6 at % and titanium may have a ratio of 17.9 at %. In this case, the ratio of molybdenum, titanium and oxygen is 2.3:1:2.

When the content of oxygen is 42.0 at %, molybdenum may have ratio of 31.3 at % and titanium may have a ratio of 21.1 at %. In this case, the ratio of molybdenum, titanium and oxygen is 1.5:1:2.

When the content of oxygen is 47.3 at %, molybdenum may have a ratio of 23.8 at % and titanium may have a ratio of 23.6 at %. In this case, the ratio of molybdenum, titanium and oxygen is 1:1:2.

That is, the atomic weight ratio of molybdenum and titanium of the low-reflection film 400 in each case may be a value for the blocking layer reflectance to be within 10%. In addition, the blocking layer reflectance may be lowest when a thickness of the low-reflection film 400 is 270 Å and the content of oxygen is 42 at %. In this case, the blocking layer reflectance is 4.5%, and the low-reflection film 400 may have a composition ratio of 31.3 at % molybdenum (Mo), 21.1 at % titanium (Ti), 42.0 at % oxygen, and 5.6 at % carbon.

The amount of destructively interfering light, which is a factor for determining the blocking layer reflectance, may also vary depending on the thickness of the low-reflection film 400.

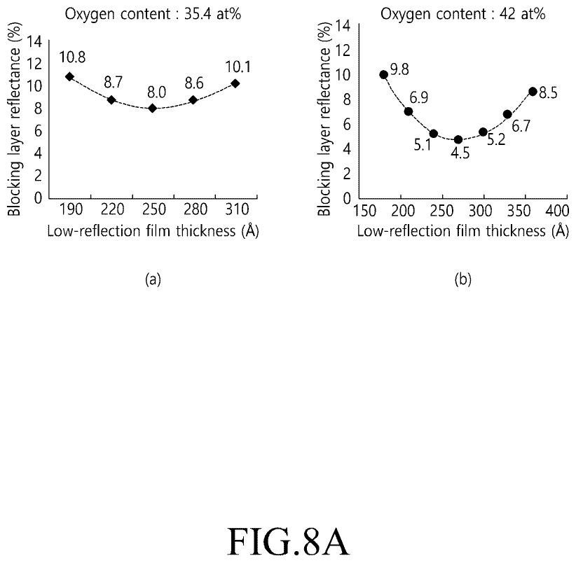

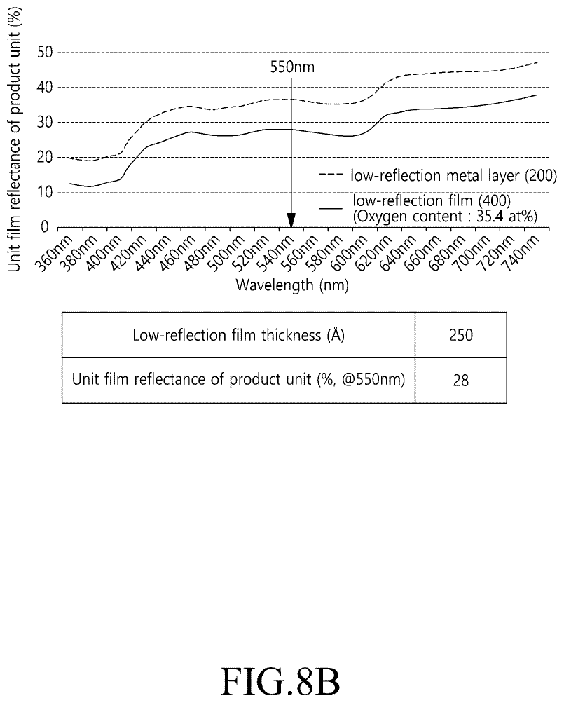

FIGS. 8A and 8B illustrate changes in optical characteristics of a display device according to modifications in configurations included in a display device according to embodiments of the present disclosure.

A graph (a) in FIG. 8A illustrates the change in reflectance of the blocking layer 133 according to the thickness of the low-reflection film 400 when the content of oxygen is 35.4 at %, and a graph (b) in FIG. 8A illustrates the change in reflectance of the blocking layer 133 according to the thickness of the low-reflection film 400 when the content of oxygen is 42 at %.

For example, in the case of (a) of FIG. 8A, the low-reflection film 400 may have a composition ratio of 41.6 at % molybdenum (Mo), 17.9% titanium (Ti), 35.4 at % oxygen, and 5.1 at % carbon. In the case of (b), the low-reflection film 400 may have a composition ratio of 31.3 at % molybdenum (Mo), 21.1 at % titanium (Ti), 42.0 at % oxygen, and 5.6 at % carbon.

In addition, (a) and (b) of FIG. 8A is a graph measuring a rate at which light with a wavelength of 550 nm is reflected from the blocking layer 133 according to a change in the thickness of the low-reflection film 400, that is, the blocking layer reflectance.

Referring to (a) of FIG. 8A, when the content of oxygen is 35.4 at %, the blocking layer 133 may have a low reflectance of 8 to 10%. In particular, the blocking layer 133 may have the lowest reflectance of 8% when the low-reflection film 400 has a thickness of 250 Å.

Referring to (b) of FIG. 8A, when the content of oxygen is 42 at %, the blocking layer 133 may have a low reflectance of 4 to 9%. In particular, the blocking layer 133 may have the lowest reflectance of 4.5% when the low-reflection film 400 has a thickness of 270 Å.

That is, as shown in (a) or (b) of FIG. 8A, the blocking layer reflectance may vary depending on the thickness of the low-reflection film 400. In particular, when the thickness of the low-reflection film 400 is in a range of approximately 150 Å to 400 Å, the blocking layer reflectance may be significantly lower compared to a case where the low-reflection film 400 is not disposed.

Therefore, a low blocking layer reflectance may be secured by adjusting the thickness of the low-reflection film 400 within the above range.

However, as shown in (a) and (b) of FIG. 8A, the blocking layer reflectance may vary depending on the content of oxygen even when the thickness of the low-reflection film 400 is the same. The reason why the reflectance varies depending on the content of oxygen is that as the content of oxygen in the low-reflection film 400 changes, the refractive index of the low-reflection film 400 changes, so that the conditions for destructive interference between the light reflected by the low reflection film 400 and the light reflected by the blocking layer 133 are changed.

For example, in (a) of FIG. 8A, it can be seen that when the thickness of the low-reflection film 400 is 250 Å, the blocking layer 133 has the lowest reflectance of 8%. However, when the content of oxygen changes as shown in (b) of FIG. 8A, that is, when the content of oxygen increases, and when the thickness of the low-reflection film 400 is the same as 250 Å, the reflectance of the blocking layer 133 is about 5.0%. That is, the blocking layer reflectance may be lowered as the content of oxygen of the low-reflection film 400 increases.

Therefore, there may be required to consider the content of oxygen contained in the low-reflection film 400 when adjusting the thickness of the low-reflection film 400 to reduce the blocking layer reflectance.

Specifically, in the case of the low-reflection film 400 with the content of oxygen of 35.4 at %, the minimum value of the blocking layer reflectance is approximately 8% when the thickness of the low-reflection film 400 is 250 Å. However, in the case of the low-reflection film 400 with the content of oxygen of 42 at %, the minimum value of the blocking layer reflectance is approximately 4.5% when the thickness of the low-reflection film 400 is 270 Å. Therefore, in order to secure the minimum value of the blocking layer reflectance, it is required to also increase the thickness of the low-reflection film 400 as the content of oxygen of the low-reflection film 400 increases.

In addition, referring to FIG. 8B, in the case of the display device 100 including the low-reflection film 400, the unit film reflectance of the product unit may also decrease.

FIG. 8B illustrates a graph comparing the unit film reflectance of each product unit of the display device 100 according to a wavelength of incident light in the cases that the thickness of the low-reflection metal layer 200 is 250 Å and the thickness of the low-reflection film 400 is 250 Å. Here, the content of oxygen of the low-reflection film 400 is 35.4 at %.

A conventional display device 100 including a low-reflection metal layer 200 with a thickness of 250 Å represents a unit film reflectance of the product unit of 36.5% based on a wavelength of 550 nm. Meanwhile, the display device 100 including the low-reflection film 400 having the same thickness instead of the low-reflection metal layer 200 may represent a unit film reflectance of the product unit of about 28% based on a wavelength of 550 nm.

Hereinafter, it will be described a method for securing a lower blocking layer reflectance according to embodiments of the present disclosure.

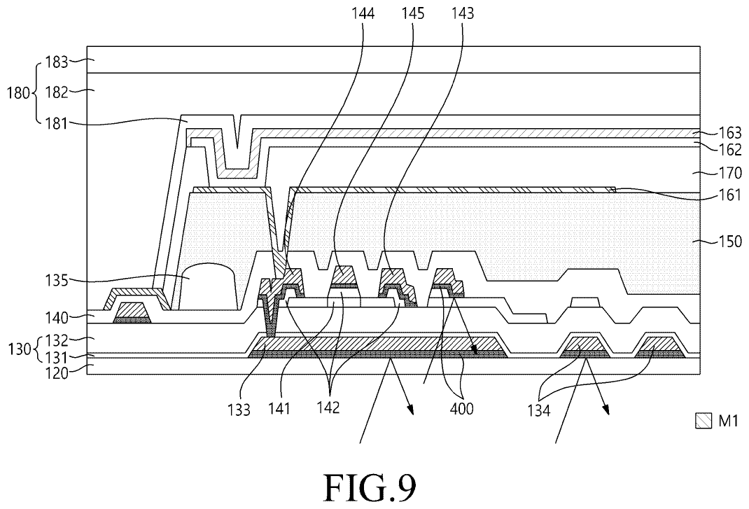

FIGS. 9 to 11 illustrate another example of a cross-sectional structure of a display device according to embodiments of the present disclosure.

The cross-sectional structure of the display device shown in FIG. 9 may be the same as the cross-sectional structure of the display device described with reference to FIG. 4 except that a low-reflection film 400 instead of a low-reflection metal layer is disposed below the source electrode 143, the drain electrode 144, and the gate electrode 145 of the driving transistor T1, so that the overlapping description will be omitted.

Referring to FIG. 9, a low-reflection film 400 may be disposed below the source electrode 143, the drain electrode 144, and the gate electrode 145 of the driving transistor T1.

The low-reflection film 400 may be disposed to cover all lower surfaces of the source electrode 143, the drain electrode 144, and the gate electrode 145. That is, the area of the lower surface of the low-reflection film 400 may be equal to or larger than the area of the lower surface of the source electrode 143, the drain electrode 144, and the gate electrode 145.

The low-reflection film 400 may be disposed between the source electrode 143, the drain electrode 144, and the interlayer insulating layer 142. That is, an upper surface of the low-reflection film 400 may be disposed in contact with a lower surface of the source electrode 143 and the drain electrode 144, and the lower surface of the low-reflection film 400 may be in contact with the upper surface of the interlayer insulating layer 142.

The low-reflection film 400 may be made of the same composition as the low-reflection film described with reference to (a) of FIG. 8A.

As an example, the low-reflection film 400 may be formed from a sputtering target of molybdenum (Mo) and titanium oxide (TiO₂), and the low-reflection film 400 may have a composition ratio of 41.6 at % molybdenum (Mo), 17.9% titanium (Ti), 35.4 at % oxygen, and 5.1 at % carbon.

In the case that the low-reflection film 400 has the same composition as the above example, the source electrode 143, drain electrode 144, and gate electrode 145 may have reflectance characteristics as shown in (a) of FIG. 8A.

That is, if the thickness of the low-reflection film 400 is 250 Å, a reflectance of the source electrode 143, the drain electrode 144, and the gate electrode 145 may be 8%, the same as the blocking layer reflectance.

However, since the low-reflection film 400 is further disposed below the source electrode 143, the drain electrode 144, and the gate electrode 145 in addition to the blocking layer 133, the unit film reflectance of the entire product unit of the display device 100 may further decrease. That is, the unit film reflectance of the product unit may be 24%.

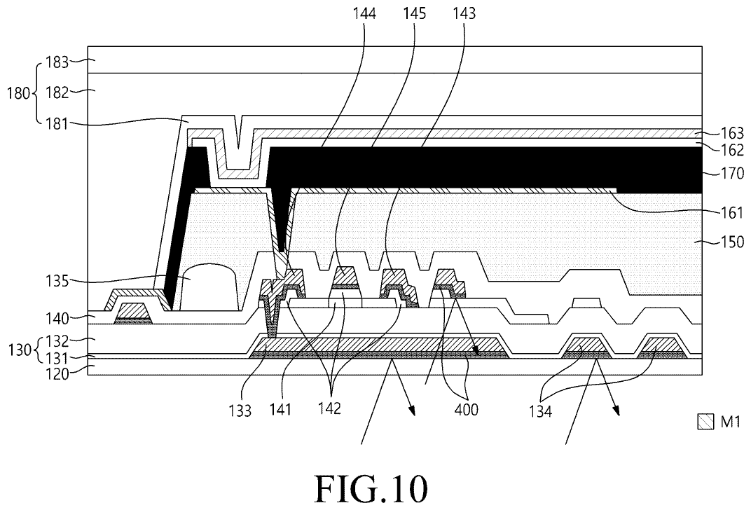

The cross-sectional structure of the display device 100 shown in FIG. 10 is the same as the cross-sectional structure of the display device described with reference to FIG. 9 except that a bank layer 170 is black, so that overlapping descriptions will be omitted.

The bank layer 170 may further include at least one of black pigment, black resin, graphite, black ink, gravure ink, black spray, and black enamel. When the bank layer 170 is made of the above materials, the bank layer can absorb at least 80% of visible light.

When the bank layer 170 is black, the bank layer 170 may absorb light incident from the outside of the display device 100, so that it is possible to further lower the unit film reflectance of the entire product unit of the display device 100. That is, the unit film reflectance of the product unit of the display device 100 may be 15%.

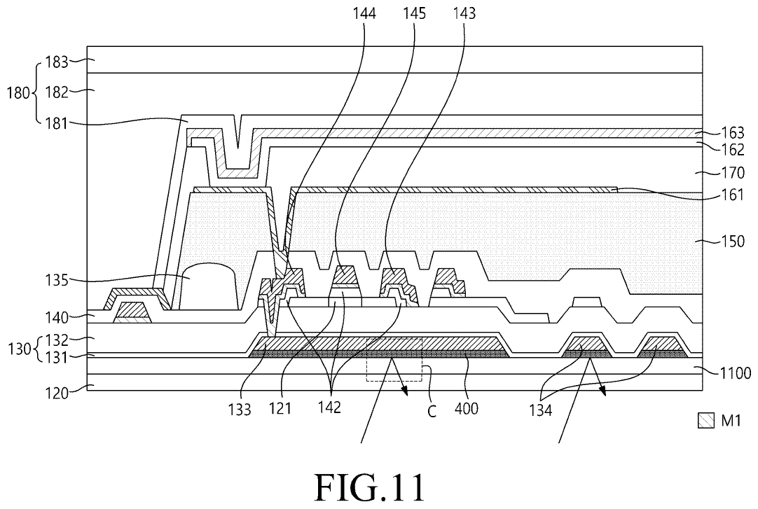

The cross-sectional structure of the display device 100 shown in FIG. 11 is the same as that described with reference to FIG. 4 except that a third buffer layer 1100 is further disposed below the low-reflection film 400 disposed below the first buffer layer 131, the blocking layer 133, and the wiring electrodes 134. Therefore, it will be omitted the redundant description.

The third buffer layer 1100 may be disposed between the substrate 120, the first buffer layer 131, and the low-reflection film 400. That is, an upper surface of the third buffer layer 1100 may contact a lower surface of the first buffer layer 131 and the low-reflective film 400, and a lower surface of the third buffer layer 1100 may contact an upper surface of the substrate 120.

The third buffer layer 1100 may be made of the same material as the first buffer layer 131 or the second buffer layer 132. For example, the third buffer layer 1100 may be made of silicon nitride (SiNx) or silicon oxide (SiOx).

The thickness of the third buffer layer 1100 may be in a range of 400 Å to 600 Å, however, is not limited thereto.

As the third buffer layer 1100 is disposed below the low-reflection film 400, the blocking layer reflectance may be further reduced.

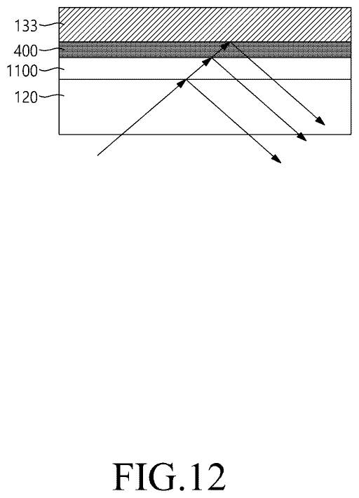

FIG. 12 is an enlarged view of part C of FIG. 11.

Referring to FIG. 12, light incident from the outside of the display device 100 may be partially reflected by the third buffer layer 1100 and partially transmitted through the third buffer layer 1100. The light transmitting through the third buffer layer 1100 may be partially reflected by the low-reflection film 400 and may partially pass through the low-reflection film 400. The light passing through the low-reflection film 400 may be reflected by the blocking layer 133.

In this case, the light reflected from the blocking layer 133 may cause a destructive interference with the light reflected from the low-reflection film 400 or the light reflected from the third buffer layer 1100.

Specifically, light reflected from the blocking layer 133 may cause the destructive interference with light reflected from the low-reflection film 400.

However, a part of the light reflected from the blocking layer 133 may not be canceled out by the light reflected from the low-reflection film 400, and may proceed toward the outside of the display device 100.

In this case, the light proceeding outward may cause additional destructive interference with the light reflected from the third buffer layer 1100.

That is, if the display device 100 further includes the third buffer layer 1100, the amount of light disappeared due to destructive interference among the light reflected from the blocking layer 133 may increase, so that the reflectance of the blocking layer of the display device 100 may be lower than the blocking layer reflectance described with reference to FIG. 4.

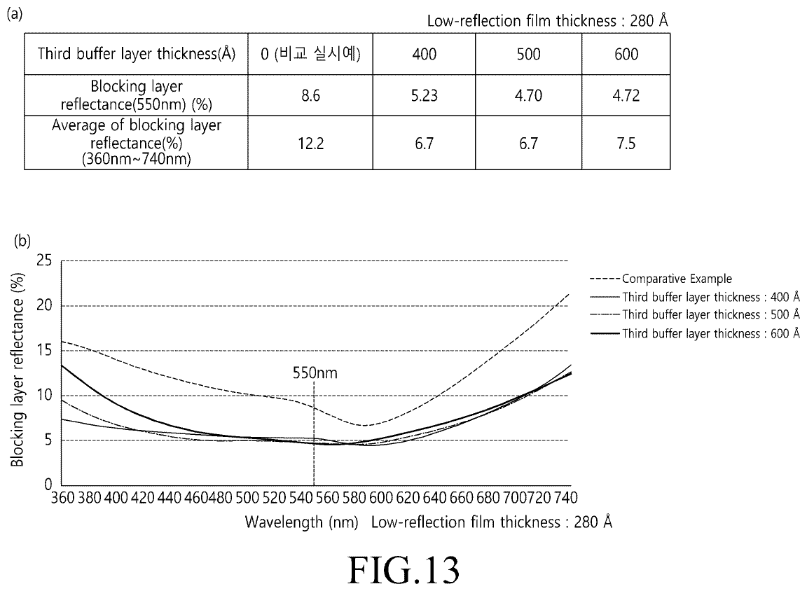

FIG. 13 illustrates optical characteristics according to wavelength of a display device shown in FIG. 11.

FIG. 13 (a) is a table representing, in the case that the thickness of the low-reflection film 400 is 280 Å, the blocking layer reflectance depending on the thickness of the third buffer layer 1100 and an average value of the blocking layer reflectance for each wavelength which varies depending on the thickness of the third buffer layer 1100. FIG. 13 (b) is a graph of the blocking layer reflectance for each wavelength which varies depending on the thickness of the third buffer layer 1100.

Referring to (a) of FIG. 13, when the thickness of the third buffer layer 1100 is 0 (i.e., comparative example), that is, when the third buffer layer 1100 is not disposed, only the low-reflection film 400 is disposed below the blocking layer 133 as shown in FIG. 4. If the thickness of the low-reflection film 400 is 280 Å, the blocking layer reflectance may be 8.6%, as shown in (a) of FIG. 8A.

Referring to (a) and (b) of FIG. 13, there may be seen that the blocking layer reflectance is further lowered if the third buffer layer 1100 is present below the low-reflection film 400. In the case that the third buffer layer 1100 has a thickness of 500 Å, the blocking layer has the lowest reflectance of 4.7%.

In addition, when the third buffer layer 1100 is disposed, there may be reduced the difference in reflectance of the blocking layer depending on the wavelength of incident light.

By adjusting the thickness of the third buffer layer 1100 as shown in (b) of FIG. 13, the light having a relatively low or relatively high wavelength among the lights reflected from the blocking layer 133 may cause more destructive interference with light reflected from the third buffer layer 1100 than light of other wavelengths.

Referring to (a) and (b) of FIG. 13, when the thickness of the third buffer layer 1100 is 0 (i.e., comparative example), that is, when the third buffer layer 1100 is not disposed, there can be seen that the average blocking layer reflectance is 12.2% when the wavelength of light incident from the outside of the display device 100 is between 360 nm and 740 nm.

That is, when light with a relatively low wavelength around 360 nm or relatively high wavelength around 740 nm is incident on the display device 100, the blocking layer reflectance may be high, so that the average blocking layer reflectance may increase.

Accordingly, the display device 100 may not properly express the color of black. That is, the black color may have a reddish or blue tint.

However, if the display device 100 includes the third buffer layer 1100, the average of the blocking layer reflectance decreases as shown in (a) and (b) of FIG. 13. For example, the average of the blocking layer reflectance may be the lowest at 6.7% when the third buffer layer 1100 has a thickness of 500 Å.

In particular, in the case of setting the thickness of the third buffer layer 1100 in the range of 400 Å to 600 Å, light with a relatively low wavelength around 360 nm or relatively high wavelength around 740 nm may cause more destructive interference with the reflected light reflected from the third buffer layer 1100, thereby reducing the average blocking layer reflectance. Therefore, there may be improves the problem that the black color of the display device 100 is not expressed properly.

That is, the display device 100 may further include the third buffer layer 1100, thereby further improving the reflection color of the display device 100.

The embodiments of the present disclosure described above are briefly described as follows.

According to an embodiment of the present disclosure, there may provide a display device including a substrate, a blocking layer disposed on the substrate, and a low-reflection film disposed below the blocking layer and including at least one metal element and oxygen, a content of oxygen being in a range of 31.6 at % to 47.3 at %.

In the display device according to an embodiment of the present disclosure, the low-reflection film may include at least one of Mo, Ti, Ni, and W.

In the display device according to an embodiment of the present disclosure, the content of Mo included in the low-reflection film may be equal to or greater than the content of Ti included in the low-reflection film.

In the display device according to an embodiment of the present disclosure, a ratio of Mo, Ti, and O included in the low-reflection film may be 3:1:2.

In the display device according to an embodiment of the present disclosure, the content of Mo included in the low-reflection film may be 47.5 at %, and the content of Ti included in the low-reflection film may be 15.9 at %.

In the display device according to an embodiment of the present disclosure, when the content of O included in the low-reflection film is 31.6 at %, the content of Mo included in the low-reflection film may be 47.5 at %, and the content of Ti included in the low-reflection film may be 15.9 at %.

In the display device according to an embodiment of the present disclosure, a ratio of Mo, Ti, and O included in the low-reflection film may be 2.3:1:2.

In the display device according to an embodiment of the present disclosure, the content of Mo included in the low-reflection film is 41.6 at %, and the content of Ti included in the low-reflection film may be 17.9 at %.

In the display device according to an embodiment of the present disclosure, when the content of O included in the low-reflection film is 35.4 at %, the content of Mo included in the low-reflection film may be 41.6 at %, and the content of Ti included in the low-reflection film may be 17.9 at %.

In the display device according to an embodiment of the present disclosure, a ratio of Mo, Ti, and O included in the low-reflection film may be 1.5:1:2.

In the display device according to an embodiment of the present disclosure, the content of Mo included in the low-reflection film may be 31.3 at %, and the content of Ti included in the low-reflection film may be 21.1 at %.

In the display device according to an embodiment of the present disclosure, when the content of O included in the low-reflection film is 42 at %, the content of Mo included in the low-reflection film may be 31.3 at %, and the content of Ti included in the low-reflection film may be 21.1 at %.

In the display device according to an embodiment of the present disclosure, a ratio of Mo, Ti, and O included in the low-reflection film may be 1:1:2.

In the display device according to an embodiment of the present disclosure, the content of Mo included in the low-reflection film may be 23.8 at %, and the content of Ti included in the low-reflection film may be 23.6 at %.

In the display device according to an embodiment of the present disclosure, when the content of O included in the low-reflection film is 47.3 at %, the content of Mo included in the low-reflection film may be 23.8 at %, and the content of Ti included in the low-reflection film may be 23.6 at %.

In the display device according to an embodiment of the present disclosure, the content of Mo included in the low-reflection film may be in a range of 23.8 at % to 47.5 at %.

In the display device according to an embodiment of the present disclosure, the content of Ti included in the low-reflection film may be in a range of 15.9 at % to 23.6 at %.

In the display device according to an embodiment of the present disclosure, the low-reflection film may be disposed between the blocking layer and the substrate, and the low-reflection film may be in contact with the substrate.

In the display device according to an embodiment of the present disclosure, a thickness of the low-reflection film may be between 150 Å and 400 Å.

The display device according to an embodiment of the present disclosure may further include a buffer layer disposed between the blocking layer and the substrate and disposed below the low-reflection film.

The display device according to an embodiment of the present disclosure may further include a transistor including a source electrode, a drain electrode and a gate electrode. The low-reflection film may be disposed below at least one of the source electrode, the drain electrode, and the gate electrode.

The display device according to an embodiment of the present disclosure may further include a black bank layer on the transistor.

In the display device according to an embodiment of the present disclosure, the low-reflection film may be formed by a sputtering process, and a target material used in the sputtering process may include metal and oxide.

In the display device according to an embodiment of the present disclosure, a sputtering target material used to form the low-reflection film may include at least one metal among Mo, Ti, Ni, and the sputtering target material used to form the low-reflection film may include at least one oxide selected from TiO₂, Ta₂O₅, MoOx, Nb₂O₅, Y₂O₃, SiO₂, ZnO, BaO, GZO, In₂O₃, MgO, WO₃, SnO₂, and ZTO.

According to an embodiment of the present disclosure, there may provide a display device including a substrate, and at least one material layer including a first material layer forming an electrode or a wiring on the substrate and including a metal element, and a second material layer disposed below the first material layer and including oxygen, a content of oxygen included in the second material layer being in a range of 31.6 at % to 47.3 at %.

In the display device according to an embodiment of the present disclosure, the second material layer may include at least one of Mo, Ti, Ni, and W.

In the display device according to an embodiment of the present disclosure, the content of Mo included in the second material layer may be in a range of 23.8 at % to 47.5%.

In the display device according to an embodiment of the present disclosure, the content of Ti included in the second material layer may be in a range of 15.9 at % to 23.6 at %.

In the display device according to an embodiment of the present disclosure, a sputtering target material used to form the second material layer may include at least one metal among Mo, Ti, Ni, and W, and the sputtering target material used to form the second material layer may include at least one oxide selected from TiO₂, Ta₂O₅, MoOx, Nb₂O₅, Y₂O₃, SiO₂, ZnO, BaO, GZO, In₂O₃, MgO, WO₃, SnO₂, and ZTO.

In the display device according to an embodiment of the present disclosure, a ratio of Mo, Ti, and O included in the second material layer may be 1.5:1:2.

In the display device according to an embodiment of the present disclosure, the content of Mo included in the second material layer may be 31.3 at %, and the content of Ti included in the second material layer may be 21.1 at %.

According to an embodiment of the present disclosure, there may provide a display device including a substrate, a blocking layer disposed on the substrate, a transistor disposed on the blocking layer and including a source electrode, a drain electrode, and a gate electrode, and a low-reflection film disposed below the blocking layer and at least one of the source electrode, the drain electrode, and the gate electrode, and including at least one metal element and oxygen, a content of the oxygen being in a range of 31.6 at % to 47.3 at %.

In the display device according to an embodiment of the present disclosure, the low-reflection film may include at least one of Mo, Ti, Ni, and W.

In the display device according to an embodiment of the present disclosure, a ratio of Mo, Ti, and O included in the low-reflection film may be 1.5:1:2.

In the display device according to an embodiment of the present disclosure, the content of Mo included in the low-reflection film may be 31.3 at %, and the content of Ti included in the low-reflection film may be 21.1 at %.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a blocking layer disposed on the substrate; and
a low-reflection film disposed below the blocking layer and including at least one metal element and oxygen, a content of oxygen being in a range of 31.6 at % to 47.3 at %.

2. The display device of claim 1, wherein an upper surface of the low-reflection film contacts a lower surface of the blocking layer.

3. The display device of claim 1, wherein the blocking layer includes an opaque material to block a light incident through the substrate.

4. The display device of claim 1, wherein a reflectance of the blocking layer below which the low-reflection film is disposed is lower than a reflectance of the blocking layer below which the low-reflection film is not disposed.

5. The display device of claim 1, further comprising a transistor disposed on the substrate,
wherein the blocking layer is disposed below the transistor.

6. The display device of claim 1, wherein the blocking layer includes an electrode for forming a wiring or a capacitor.

7. The display device of claim 1, wherein the low-reflection film includes at least one of Mo, Ti, Ni, and W.

8. The display device of claim 7, wherein the content of Mo included in the low-reflection film is equal to or greater than the content of Ti included in the low-reflection film.

9. The display device of claim 7, wherein a ratio of Mo and Ti included in the low-reflection film ranges from 1:1 to 3:1.

10. The display device of claim 9, wherein a ratio of Ti and O included in the low-reflection film is 1:2.

11. The display device of claim 10, wherein the content of Mo included in the low-reflection film is 47.5 at %, and the content of Ti included in the low-reflection film is 15.9 at %.

12. The display device of claim 11, wherein, when the content of O included in the low-reflection film is 31.6 at %.

13. The display device of claim 10, wherein the content of Mo included in the low-reflection film is 41.6 at %, and the content of Ti included in the low-reflection film is 17.9 at %.

14. The display device of claim 13, wherein, when the content of O included in the low-reflection film is 35.4 at %.

15. The display device of claim 10, wherein the content of Mo included in the low-reflection film is 31.3 at %, and the content of Ti included in the low-reflection film is 21.1 at %.

16. The display device of claim 15, wherein, when the content of O included in the low-reflection film is 42 at %.

17. The display device of claim 10, wherein the content of Mo included in the low-reflection film is 23.8 at %, and the content of Ti included in the low-reflection film is 23.6 at %.

18. The display device of claim 17, wherein, when the content of O included in the low-reflection film is 47.3 at %.

19. The display device of claim 7, wherein the content of Mo included in the low-reflection film is in a range of 23.8 at % to 47.5 at %.

20. The display device of claim 7, wherein the content of Ti included in the low-reflection film is in a range of 15.9 at % to 23.6 at %.

21. The display device of claim 1, wherein the low-reflection film is disposed between the blocking layer and the substrate, and a lower surface of the low-reflection film is in contact with the substrate.

22. The display device of claim 1, wherein a thickness of the low-reflection film is between 150 Å and 400 Å.

23. The display device of claim 1, further comprising a buffer layer disposed between the substrate and the low-reflection film.

24. The display device of claim 23, wherein the buffer layer includes silicon nitride or silicon oxide.

25. The display device of claim 23, wherein a thickness of the buffer layer is between 400 Å and 600 Å.

26. The display device of claim 1, further comprising a transistor disposed on the substrate, the transistor including a source electrode, a drain electrode and a gate electrode,
wherein the low-reflection film is further disposed below at least one of the source electrode, the drain electrode, and the gate electrode.

27. The display device of claim 5, further comprising a black bank layer on the transistor.

28. The display device of claim 1, wherein the low-reflection film is formed by a sputtering process, and a target material used in the sputtering process includes metal and oxide.

29. The display device of claim 1, wherein a sputtering target material used to form the low-reflection film includes at least one metal among Mo, Ti, Ni, and W, and includes at least one oxide selected from TiO₂, Ta₂O₅, MoOx, Nb₂O₅, Y₂O₃, SiO₂, ZnO, BaO, GZO, In₂O₃, MgO, WO₃, SnO₂, and ZTO.

30. A display device, comprising:
a substrate; and
at least one material layer including a first material layer forming an electrode or a line on the substrate and including a metal element, and a second material layer disposed below the first material layer and including oxygen, a content of oxygen included in the second material layer being in a range of 31.6 at % to 47.3 at %.

31. The display device of claim 30, wherein the second material layer includes at least one of Mo, Ti, Ni, and W.

32. The display device of claim 31, wherein the content of Mo included in the second material layer is in a range of 23.8 at % to 47.5 at %.

33. The display device of claim 31, wherein the content of Ti included in the second material layer is in a range of 15.9 at % to 23.6 at %.

34. The display device of claim 30, wherein a sputtering target material used to form the second material layer includes at least one metal among Mo, Ti, Ni, and W, and includes at least one oxide selected from TiO₂, Ta₂O₅, MoOx, Nb₂O₅, Y₂O₃, SiO₂, ZnO, BaO, GZO, In₂O₃, MgO, WO₃, SnO₂, and ZTO.

35. The display device of claim 31, wherein a ratio of Mo, Ti, and O included in the second material layer is 1.5:1:2.

36. The display device of claim 31, wherein the content of Mo included in the second material layer is 31.3 at %, and the content of Ti included in the second material layer is 21.1 at %.

37. A display device, comprising:
a substrate;
a blocking layer disposed on the substrate;
a transistor disposed on the blocking layer and including a source electrode, a drain electrode, and a gate electrode; and
a low-reflection film disposed below the blocking layer and at least one of the source electrode, the drain electrode, and the gate electrode, and including at least one metal element and oxygen, a content of the oxygen being in a range of 31.6 at % to 47.3 at %.

38. The display device of claim 37, wherein the low-reflection film comprises at least one of Mo, Ti, Ni, and W.

39. The display device of claim 38, wherein a ratio of Mo, Ti, and O included in the low-reflection film is 1.5:1:2.

40. The display device of claim 38, wherein the content of Mo included in the low-reflection film is in a range of 23.8 at % to 47.5 at %.

41. The display device of claim 38, wherein the content of Ti included in the low-reflection film is in a range of 15.9 at % to 23.6 at %.
